(19) United States
(12) Patent Application Publication
(10) Pub. No.: US 2020/0411743 A1
(43) Pub. Date: Dec. 31, 2020

(54) Thermoelectric Materials And Process For The Preparation Thereof

(71) Applicants: Council of Scientific and Industrial Research, New Delhi (IN); GAIL INDIA LIMITED, Noida Uttar Pradesh (IN)

(72) Inventors: Biswapriya Deb, Thiruvananthapuram, Kerala (IN); Vijayakumar Chakkooth, Thiruvananthapuram, Kerala (IN); Vijitha Ignatious, Thiruvananthapuranm, Kerala (IN); Manoj Ramakrishna Meshram, Noida Uttar Pradesh (IN); Jaivinder Singh, Noida Uttar Pradesh (IN); Tanjore Puli Yuvaraj, Noida Uttar Pradesh (IN)

(73) Assignees: Council of Scientific and Industrial Research, New Delhi (IN); GAIL INDIA LIMITED, Noida Uttar Pradesh (IN)

(21) Appl. No.: 16/979,019

(22) PCT Filed: Sep. 16, 2019
(86) PCT No.: PCT/IN2019/050675

§ 371 Date: Sep. 8, 2020

(30) Foreign Application Priority Data
Sep. 19, 2018 (IN) 201811035273

(51) Int. Cl. H01L 35/24; H01L 35/32; H01L 35/34; H01L 51/00

(52) U.S. Cl. CPC H01L 35/24; H01L 35/32; H01L 51/0036; H01L 51/0048; H01L 35/34

(57) ABSTRACT

The present invention provides thermoelectric composite materials that comprise a physical mixture of semiconducting polymers and carbon nanotube structures. The present invention further provides a process to improve the thermoelectric power factor of the composite by doping with inorganic salts.

### FIELD OF THE INVENTION

The present invention relates to a thermoelectric composite material comprising of fused thiophene based semiconducting polymer of formula I, carbon nanotube structures optionally along with oxidizing salts as dopants.

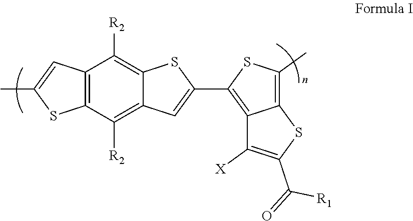

wherein
R1=—C₇H₁₅;
R2 is identical and selected from

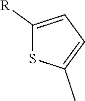

### or —OR

R=—C₈H₁₇;
X=H or F when R2 is

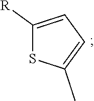

X=H when R2 is —OR.

Particularly, present invention relates to the thermoelectric device comprising of thermoelectric composite material of fused thiophene based semiconducting polymers of Formula I, carbon nanotube structures optionally along with oxidizing salts as dopants.

More particularly, present invention relates to a process for the preparation of thermoelectric composite material.

### BACKGROUND AND PRIOR ART OF THE INVENTION

The most fundamental thermoelectric phenomenon is the Seebeck effect, in which the temperature difference across a material creates a voltage difference, causing charges to move from the hot end to the cold end of the material. Another related effect is the Peltier effect, in which either the absorption or rejection of heat would take place, depending on the direction of the current. The factor which characterize the thermoelectric materials is dimensionless Figure of Merit (ZT), which depends on electrical conductivity (σ, with charge carrier of electrons for n-type and holes for p-type materials), Seebeck coefficient (α, positive for p-type and negative for n-type), and thermal conductivity (κ) as shown in the following relation.

ZT=α²σT/κ

A good thermoelectric material should have high electrical conductivity to minimize Joule heating, low thermal conductivity to prevent thermal shorting, and a high Seebeck coefficient for maximum conversion of heat to electrical power or electrical power to cooling. The ZT value indicates the ability of conversion between heat and electrical power.

Theoretical predictions performed by Hicks and Dresselhaus suggested that the thermoelectric efficiency could be greatly enhanced by quantum confinement of the electron charge carriers [Reference may be made to Hicks, L. D. et al. Phys. Rev. B, 1993, 47, 12727].

The lattice thermal conductivity can be reduced without altering electrical conductivity by means of nanofabrication [Reference may be made to Harman, T. C. et al., Science, 2002, 297, 2229].

However, the organic polymers has intrinsic advantage of having very low thermal conductivity due to their comparable phonon mean free path with minimum separation between equivalent structural units [Reference may be made to Bubnova, O. et al., Nature Mater., 2011, 10, 429].

So far, a variety of organic polymer based thermoelectric materials have been realized. Most of the organic polymer thermoelectric materials are conducting polymers such as PEDOT, PANI, polythiophene, polypyrrole and their derivatives [Reference may be made to Hu, X. et al., J. Mater. Chem. A, 2015, 3, 20896].

New organic based systems such as ethylenetetrathiolate, 2,7-Dialkyl[1]benzothieno[3,2-b][1]benzothiophene derivatives and several other thiophene:polystyrenesulfonate based materials show good promise [Reference may be made to Sheng, P. et al, Synthetic Metals, 2014, 193, 1; Shi, W. et al, Chem. Mater., 2014, 26, 2669; Lee, S. H. et al., J. Mater. Chem. A, 2014, 2, 7288; Wang, Y. Y. et al., J. Phys. Chem. C, 2013, 117, 24716; Kim, G. H. et al., Nature Mater., 2013, 12, 719; Kim, D. et al., ACS Nano, 2014, 4, 2445; Jiang, Q. et al., J. Electron. Mater., 2015, 44, 1585].

The above mentioned organic polymer based thermoelectric materials are still not good enough for practical use due to lack of stability. Therefore, a thermoelectric composite material with a high efficiency of heat-power conversion and a device using the same is required.

### Abbreviations Used

### SEM—Scanning Electron Microscopy

### TEM—Transmission Electron Microscopy

PEDOT—Poly(3,4-ethylenedioxythiophene)

### PANI—Polyaniline

PBDTTT-C-T—Poly[(4,8-bis[5-(2-ethylhexyl)-2-thienyl]benzo[1,2-b:4,5-b′]dithiophene-2,6-diyl][2-(2-ethyl-1-oxohexyl)thieno[3,4-b]thiophenediyl)]
PBDTTT-C—Poly[(4,8-bis-(2-ethylhexyl)-benzo(1,2-b:4,5-b′)dithiophene)-2,6-diyl-alt-(4-(2-ethylhexanoyl)-thieno[3,4-b]thiophene-)-2-6-diyl)]
PBDTT-FTTE—Poly[4,8-bis(5-(2-ethylhexyl)thiophen-2-yl)benzo[1,2-b;4,5-b′]dithiophene-2,6-diyl-alt-(4-(2-ethylhexyl)-3-fluorothieno[3,4-b]thiophene-)-2-carboxylate-2-6-diyl)]

### DMF—Dimethylformamide

DMSO—Dimethyl sulfoxide
NMP—N-Methyl-2-pyrrolidone

### THF—Tetrahydrofuran

### Cl₂—Chlorine

### Br₂—Bromine

### I₂—Iodine

ICl—Iodine monochloride
ICl₃—Iodine trichloride
IBr—Iodine monobromide
PF₅—Phosphorus pentafluoride
SbF₅—Antimony pentafluoride
SOS—Sulfur trioxide
BCl₃—Boron trichloride
BF₃—Boron trifluoride
FeCl₃—Ferric chloride
FeOCl—Iron oxychloride
TiCl₄—Titanium chloride
CuCl₂—Copper (II) chloride
ZnCl₂—Zinc (II) chloride
LiCl—Lithium chloride
TaCl₅—Tantalum chloride
MoCl₅—Molybdenum (V) chloride
WCl₆—Tungsten (VI) chloride
WF₆—Tungsten hexafluoride
NbF₅—Niobium (V) fluoride
NbCl₅—Niobium (V) chloride
ZrCl₄—Zirconium tetrachloride
NiCl₂—Nickel (II) chloride

### TCNQ—Tetracyanoquiodimethane

ITO—Indium doped Tin Oxide
FTO—Fluorine doped Tin Oxide
PET—Polyethylene terephthalate
MWCNT—Multi-walled carbon nanotube

### RF—Radio Frequency

### OBJECTIVES OF THE INVENTION

The main object of the present invention is to provide a thermoelectric composite material comprising of fused thiophene based semiconducting polymers and carbon nanotube structures.

Another object of the present invention is to provide thermoelectric composite material comprising of fused thiophene based semiconducting polymers, carbon nanotube structures and oxidizing salts as dopants.

Yet another object of the present invention is to provide thermoelectric conversion devices consisting of above mentioned composites.

### SUMMARY OF THE INVENTION

Accordingly, present invention provides a thermoelectric composite material comprising, 15 to 75 weight percent a semiconducting polymer of formula I, 25 to 85 weight percent a carbon nanotube structure.

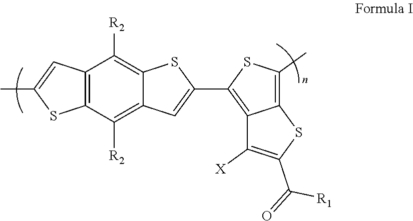

wherein
R1=—C₇H₁₅;
R2 is identical and selected from

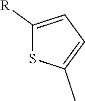

### or —OR

R=—C₈H₁₇;
X=H or F when R2 is

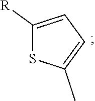

X=H when R2 is —OR.

In an embodiment of the present invention, thermoelectric composite material comprising, 15 to 75 weight percent a semiconducting polymer of formula I, 25 to 85 weight percent a carbon nanotube structure optionally along with 0.005 to 0.3 molar concentration of a dopant.

In another embodiment of the present invention, formula I is selected from the group consisting of:

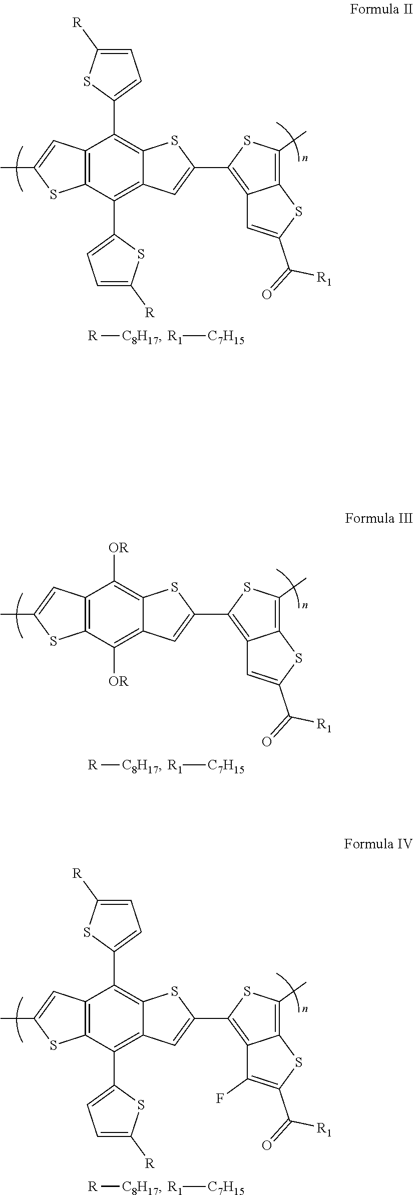

In yet another embodiment of the present invention, the carbon nanotubes is selected from single-walled, double-walled, and/or multi-walled carbon nanotubes.

In still another embodiment of the present invention, the dopant used is selected from a group consisting of an onium salt compound, an oxidizing agent, an acidic compound and an electron acceptor compound.

In yet another embodiment of the present invention, the dopant is a transition metal using its salt compound.

In still another embodiment of the present invention, the composite material is stable up to 350° C. and is capable of producing a potential difference in response to a temperature gradient.

In yet another embodiment, present invention provides conductivity of the device in the range of 400 S/m to 2000 S/m.

In still another embodiment, present invention provides a preparation method of thermoelectric composite materials comprising the steps of:
i. incorporating the 25 to 85 weight percent of carbon nanotube in 15 to 75 weight percent fused thiophene based semiconducting polymer of formula I in the presence of a solvent followed by application of ultrasonic waves for 45 to 65 min to obtain thermoelectric composite materials.

In yet another embodiment, present invention provides a thermoelectric conversion device comprising serially connected single or multiple planar legs made of a thermoelectric composite material as claimed in claims 1 and 2, casted on a substrate or made as a free-standing leg and supported by the second substrate for insulation from the surrounding.

In still another embodiment of the present invention, fused thiophene polymer is preferably in the range of 15 to 75% by mass, preferably 25 to 65% by mass and particularly preferable in a range of 45 to 55% by mass in the total solid content.

In yet another embodiment of the present invention, mean length of the carbon nanotube used in the present invention is not particularly limited, is preferably 0.1 μm or more to 100 μm or less, and more preferably 1 μm or more to 10 μm or less.

In still another embodiment of the present invention, diameter of the carbon nanotube used is not particularly limited, is preferably 0.4 nm or more to 500 nm or less, more preferably 300 nm or less, and further preferably 200 nm or less.

In yet another embodiment of the present invention, the content of carbon nanotube is preferably 25 to 85% by mass, more preferably 35 to 65% by mass, and particularly preferably 45 to 55% by mass, in the total solid content.

In yet another embodiment of the present invention, the thermoelectric composite material of the present invention preferably contains a solvent.

In still another embodiment of the present invention, the solvent may be any solvent capable of satisfactorily dissolving or dispersing the components.

In yet another embodiment of the present invention, the solvent is an organic polar solvent and mixed solvents thereof.

In still another embodiment of the present invention, the solvent is preferably an organic solvent, water and preferred examples include halogen-based solvents such as chloroform, aprotic polar solvents such as DMF, DMSO and NMP; alcohols; aromatic solvents such as chlorobenzene, xylene, benzene, toluene, dichlorobenzene, mesitylene, tetralin, tetramethyl benzene, and pyridine; ketone-based solvents such as methyl ethyl ketone, cyclohexanone, and acetone; and ether-based solvents such as diethyl ether, t-butyl methyl ether, diglyme, THF, and dimethoxyethane, and more preferred examples include halogen-based solvents such as chloroform, aprotic polar solvents such as NMP and DMF; aromatic solvents such as dichlorobenzene, xylene, tetralin, and tetramethyl benzene; and ether-based solvents such as THF.

In yet another embodiment of the present invention, the amount of the solvent in the thermoelectric composite material is preferably 80% to 99.99% by mass, more preferably 90% to 99.98% by mass, and further preferably 95% to 99.95% by mass, relative to the total amount of the thermoelectric composite material.

In still another embodiment of the present invention, the dopant is a compound that is doped into the semiconducting polymer and may be any compound capable of doping the polymer to have a positive charge (p-type doping) by protonizing the polymer or eliminating electrons from the 7-conjugated system of the polymer.

In yet another embodiment of the present invention, the dopant is selected from a group consisting of an onium salt compound, an oxidizing agent, an acidic compound, an electron acceptor compound.

In still another embodiment of the present invention, the onium salt compounds, include a sulfonium salt, an iodonium salt, an ammonium salt, a carbonium salt, and a phosphonium salt.

In yet another embodiment of the present invention, the oxidizing agent include halogen (Cl₂, Br₂, I₂, ICl, ICl₃, IBr), Lewis acid (PF₅, SbF₅, SO₃, BCl₃, BF₃), a metal halide salt (FeCl₃, FeOCl, TiCl₄, CuCl₂, ZnCl₂, LiCl, TaCl₅, MoCl₅, WCl₆, WF₆, NbF₅, NbCl₅, ZrO₄, NiCl₂).

In still another embodiment of the present invention, the acidic compounds include a hydroxyl compound, poly phosphoric acid, a carboxy compound and a sulfonic compound, various organic acids, amino acids and the like.

In yet another embodiment of the present invention, an electron acceptor compound includes TCNQ, hetero cyclic thiadiazole, phthalocyanine, carborane-based compounds, halogenated tetracyanoquinodimethane, pyrazine, tetrazine, pyridine, pyridopyrazine and other boron atom-containing compounds. Specifically, a metal chloride salt, FeCl₃, ZnCl₂, CuCl₂.

In still another embodiment of the present invention, the concentration of the dopant is preferably 0.001 M to 0.1 M, more preferably 0.01 to 0.05 M.

In yet another embodiment of the present invention, the time for doping treatment is preferably 1 minute to 60 minutes, more preferably, 10 minutes to 40 minutes, and particularly preferably 20 minutes to 30 minutes.

### BRIEF DESCRIPTION OF THE FIGURES

FIG. 1 represents the schematic structural view of a thermoelectric composite material without doping.

FIG. 2 represents the SEM image of the formula II polymer and carbon nanotube thermoelectric composite material.

FIG. 3 represents the TEM image of the formula II polymer and carbon nanotube thermoelectric composite material.

FIG. 4 represents the SEM image of the formula III polymer and carbon nanotube thermoelectric composite material.

FIG. 5 represents the TEM image of the formula III polymer and carbon nanotube thermoelectric composite material.

FIG. 6 represents the SEM image of the formula IV polymer and carbon nanotube thermoelectric composite material.

FIG. 7 represents the TEM image of the formula IV polymer and carbon nanotube thermoelectric composite material.

FIG. 8 represents the distribution of electrical conductivity of the thermoelectric conversion layer without doping for formula II, formula III and formula IV polymers and carbon nanotube.

FIG. 9 represents the distribution of Seebeck coefficient of the thermoelectric conversion layer without doping for formula II, formula III and formula IV polymers and carbon nanotube.

FIG. 10 represents the distribution of power factor of the thermoelectric conversion layer without doping for formula II, formula III and formula IV polymers and carbon nanotube.

FIG. 11 represents the schematic structural view of the thermoelectric composite material with doping.

FIG. 12 represents the distribution of electrical conductivity of the thermoelectric conversion layer with doping for formula II, formula III and formula IV polymers and carbon nanotube.

FIG. 13 represents the distribution of Seebeck coefficient of the thermoelectric conversion layer with doping for formula II, formula III and formula IV polymers and carbon nanotube.

FIG. 14 represents the distribution of power factor of the thermoelectric conversion layer with doping for formula II, formula III and formula IV polymers and carbon nanotube.

FIG. 15 represents a thermoelectric conversion device using the thermoelectric composite material.

### DETAIL DESCRIPTION OF THE INVENTION

Present invention provides a semiconducting polymers and carbon nanotube based thermoelectric composite materials and thermoelectric conversion devices using the same.

The present invention provides new thermoelectric composites through an industrially viable and cost effective process for the preparation that is composed of fused thiophene based semiconducting polymers and carbon nanotube structures. The thermoelectric power factor of the composite could be further enhanced through the doping of oxidizing salts.

The semiconducting polymers in the thermoelectric composite material of the present invention are fused thiophene polymers, having two or more thiophene units fused together or with a benzene unit (Formula I). The fused thiophene units may or may not contain fluorine atoms. The fused thiophene structures are also incorporated with long alkyl chains or branched alkyl chains or the like. R represents long alkyl chains or branched alkyl chains having 1 to 20 carbon atoms.

The Formula II (PBDTTT-C-T) is a benzodithiophene flanked by two thiophenes at the 4, 8 positions, and thieno thiophene unit.

The Formula III (PBDTTT-C) contains ethylhexyloxy alkyl part of benzodithiophene and thieno thiophene unit with ethylhexanoyl as the alkyl part.

The Formula IV (PBDTT-FTTE) contains fluorine attached thieno thiophene unit, and benzodithiophene unit contains a benzene ring with two thiophene units are attached.

The content of fused thiophene copolymer in the thermoelectric composite material is in the total solid content preferably in a range of 15 to 75% by mass, preferably 25 to 65% by mass and particularly preferable in a range of 45 to 55% by mass in the total solid content.

The carbon nanotubes in the carbon nanotube structure in the present invention includes single-walled, double-walled, and/or multi-walled carbon nanotubes. The carbon nanotube structure includes a single-walled carbon nanotube in which one sheet of graphene is wound cylindrically, a double-walled carbon nanotube in which two graphene sheets are wound concentrically, and a multi-walled carbon nanotube in which a bundle of graphene sheets is wound concentrically. Each layer of the bundled carbon nanotube films is coated with one electrically semiconducting polymer layer.

The thermoelectric composite material of the present invention is prepared by mixing the above described components by dissolving or dispersing those in a solvent by shaking, stirring or kneading. The dissolution or dispersion may accelerate by an ultrasonication treatment.

The thermoelectric composite material in the present invention contains oxidizing agent as a dopant. The dopant is incorporated before or after the film formation of the thermoelectric composite materials in the present invention.

The thermoelectric conversion device of the present invention consists of the thermoelectric composite materials mentioned above. The thermoelectric conversion device is an element that includes a substrate, thermoelectric conversion layer and electrodes that electrically connect these.

A thermoelectric conversion device works under the condition of keeping a temperature difference between both the ends of a thermoelectric conversion layer, and it is necessary to form a shape having a certain thickness with a thermoelectric conversion layer from a thermoelectric composite material. Therefore, a thermoelectric composite material is required to have good coating property or film-forming property.

The thermoelectric composite material of the present invention has a sufficiently high thermoelectric conversion ability to be used as a thermoelectric composite material and also has good dispersibility of carbon nanotube and excellent coating property or film-forming property so that the thermoelectric composite material is suitable for a thermoelectric conversion layer.

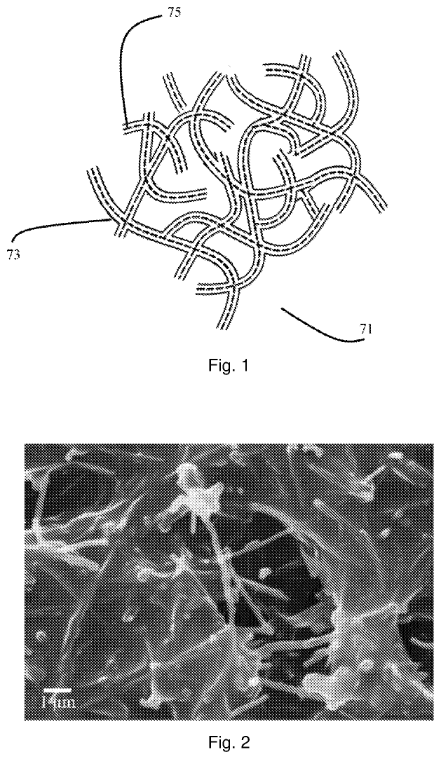

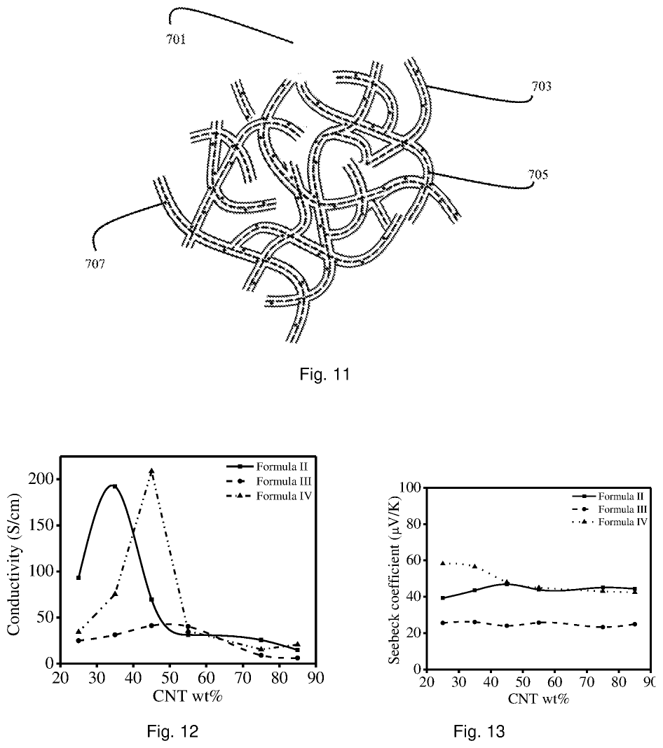

FIG. 1 refers a thermoelectric composite material (71) includes a carbon nanotube structure (75) and fused thiophene polymer (73) layer. The carbon nanotube structure works as a framework. The fused thiophene based semiconducting polymer layer (73) is coated on the surfaces of the carbon nanotube structure (75). That is, the polymer layer is supported by the carbon nanotube structure. FIG. 11 refers a thermoelectric composite material (701) includes a carbon nanotube structure (705) and fused thiophene polymer (703) layer along with the dopant (707).

A mean length of the carbon nanotube used in the present invention is not particularly limited, but from viewpoints of ease of electrical conductivity, film-forming property, or the like, the mean length of the carbon nanotube is preferably 0.1 μm or more to 100 μm or less, and more preferably 1 μm or more to 10 μm or less.

A diameter of the carbon nanotube used in the present invention is not particularly limited, but from viewpoints of durability, film-forming property, electrical conductivity, or the like, the diameter is preferably 0.4 nm or more to 500 nm or less, more preferably 300 nm or less, and further preferably 200 nm or less.

In the thermoelectric composite material, the content of carbon nanotube is preferably 25 to 85% by mass, more preferably 35 to 65% by mass, and particularly preferably 45 to 55% by mass, in the total solid content.

The thermoelectric composite material of the present invention preferably contains a solvent. The thermoelectric composite material of the present invention is more preferably a carbon nanotube dispersion liquid in which carbon nanotubes are dispersed in a solvent.

The solvent may be any solvent capable of satisfactorily dissolving or dispersing the components. An organic solvent and mixed solvents thereof is used. The solvent is preferably an organic solvent, water and preferred examples include halogen-based solvents such as chloroform, aprotic polar solvents such as DMF, DMSO and NMP; alcohols; aromatic solvents such as chlorobenzene, xylene, benzene, toluene, dichlorobenzene, mesitylene, tetralin, tetramethyl benzene, and pyridine; ketone-based solvents such as methyl ethyl ketone, cyclohexanone, and acetone; and ether-based solvents such as diethyl ether, t-butyl methyl ether, diglyme, THF, and dimethoxyethane, and more preferred examples include halogen-based solvents such as chloroform, aprotic polar solvents such as NMP and DMF; aromatic solvents such as dichlorobenzene, xylene, tetralin, and tetramethyl benzene; and ether-based solvents such as THF.

The amount of the solvent in the thermoelectric composite material is preferably 80% to 99.99% by mass, more preferably 90% to 99.98% by mass, and further preferably 95% to 99.95% by mass, relative to the total amount of the thermoelectric composite material.

A dopant is presented in the thermoelectric composite material of the present invention. The dopant is incorporated through mixing, dipping, soaking, electrophoresis or infusing techniques or the like, more preferably, soaking and the likes is used. The dopant is a compound that is doped into the semiconducting polymer and may be any compound capable of doping the polymer to have a positive charge (p-type doping) by protonizing the polymer or eliminating electrons from the π-conjugated system of the polymer. Specifically, an onium salt compound, an oxidizing agent, an acidic compound, an electron acceptor compound and the like is used.

The onium salt compounds, specific examples include a sulfonium salt, an iodonium salt, an ammonium salt, a carbonium salt, and a phosphonium salt. Specific examples of the oxidizing agent to be used as the dopant include halogen (Cl₂, Br₂, I₂, ICl, ICl₃, IBr), Lewis acid (PF₅, SbF₅, SO₃, BCl₃, BF₃), a metal halide salt (FeCl₃, FeOCl, TiCl₄, CuCl₂, ZnCl₂, LiCl, TaCl₅, MoCl₅, WCl₆, WF₆, NbF₅, NbCl₅, ZrCl₄, NiCl₂). The acidic compounds include a hydroxyl compound, poly phosphoric acid, a carboxy compound and a sulfonic compound, various organic acids, amino acids and the like. An electron acceptor compound includes TCNQ, hetero cyclic thiadiazole, phthalocyanine, carborane-based compounds, halogenated tetracyanoquinodimethane, pyrazine, tetrazine, pyridine, pyridopyrazine and other boron atom-containing compounds. Specifically, a metal chloride salt, FeCl₃, ZnCl₂, CuCl₂ and the like is used.

The thermoelectric composite material of the present invention is prepared by mixing the above described various components. There are no particular limitations on the method for preparing a thermoelectric composite material, and the material preparation is carried out at normal temperature and normal pressure using a conventional mixing apparatus or the like. For example, the material is prepared by dispersing or dissolving various components in a solvent by shaking, stirring or kneading. The dissolution or dispersion may accelerate by an ultra-sonication treatment.

The thermoelectric composite material of the present invention is converted into a thermoelectric conversion layer. The thermoelectric conversion layer is any layer obtainable by shaping the thermoelectric composite material on a substrate, and there are no particular limitations on the shape, preparation method and the like. The thermoelectric conversion layer is formed by coating the thermoelectric composite material of the present invention, on a substrate and forming a film.

The method of film forming is not particularly limited, and for example, known methods such as blade coating, spray coating, spin coating, extrusion die coating, roll coating, bar coating, screen printing, curtain coating, inkjet printing, stencil printing and dip coating can be used. If necessary, a drying process is carried out after coating. As the substrate, a base material such as glass, metal, ceramics, and a plastic film are used. In particular, a substrate on which various kinds of electrode materials are arranged with the thermoelectric conversion layer is preferably used. As the electrode material, a transparent electrode such as ITO and FTO, a metal electrode such as silver, copper, gold and aluminum, a semiconducting paste into which semiconducting particulates such as silver and carbon are dispersed, and a semiconducting paste containing a metal nanowire of silver, copper, and aluminum is used.

The thermoelectric conversion device of the present invention is an element having a thermoelectric conversion leg using the thermoelectric composite material of the present invention, and the configuration thereof is not particularly limited. Preferably, the thermoelectric conversion device is an element including a substrate and a thermoelectric conversion leg provided on the substrate, and further having electrodes that electrically connect the thermoelectric conversion leg. Even more preferably, the thermoelectric conversion device is an element having a pair of electrodes provided on a substrate, and a thermoelectric conversion leg deposited or placed between the electrodes.

### EXAMPLES

The following examples are given by the way of illustration and therefore should not be construed to limit the scope of the invention.

### Example 1

### Preparation of Polymer Composite Using Polymer of Formula II and MWCNT

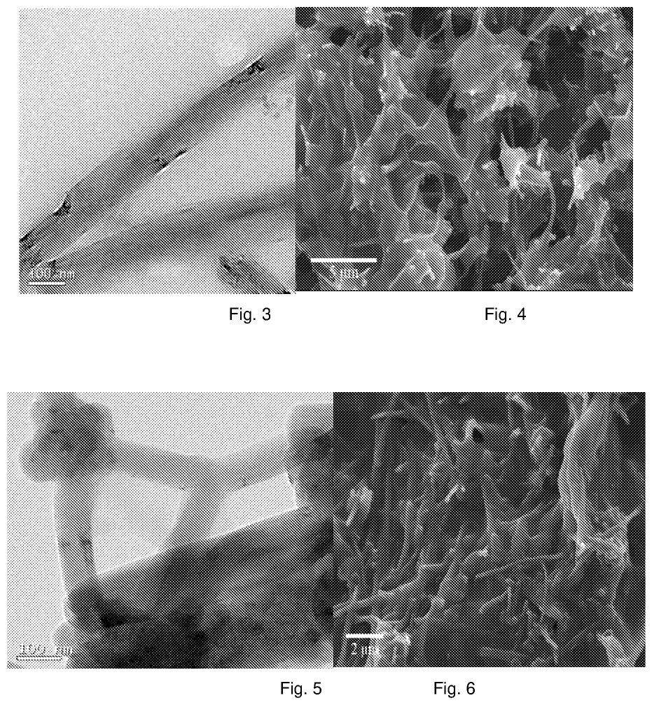

The 45 weight percent of carbon nanotube is incorporated into 55 weight percent of fused thiophene polymer matrix in the presence of 1,2-dichlorobenzene by applying ultrasonic waves. The composite is treated with ultrasonic waves of 80 kHz frequency at a low power sonication (192 W) for 1 hour at 30° C. The FIG. 2 and FIG. 3 corresponds to the microscopic image of formula II polymer and carbon nanotube thermoelectric composite materials.

### Example 2

### Preparation of Polymer Composite Using Polymer of Formula III and MWCNT

The 45 weight percent of carbon nanotube is incorporated into 55 weight percent of fused thiophene polymer matrix in the presence of 1,2-dichlorobenzene by applying ultrasonic waves. The composite is treated with ultrasonic waves of 80 kHz frequency at a low power sonication (192 W) for 1 hour at 30° C. The FIG. 4 and FIG. 5 corresponds to the microscopic image of formula Ill polymer and carbon nanotube thermoelectric composite materials.

### Example 3

### Preparation of Polymer Composite Using Polymer of Formula IV and MWCNT

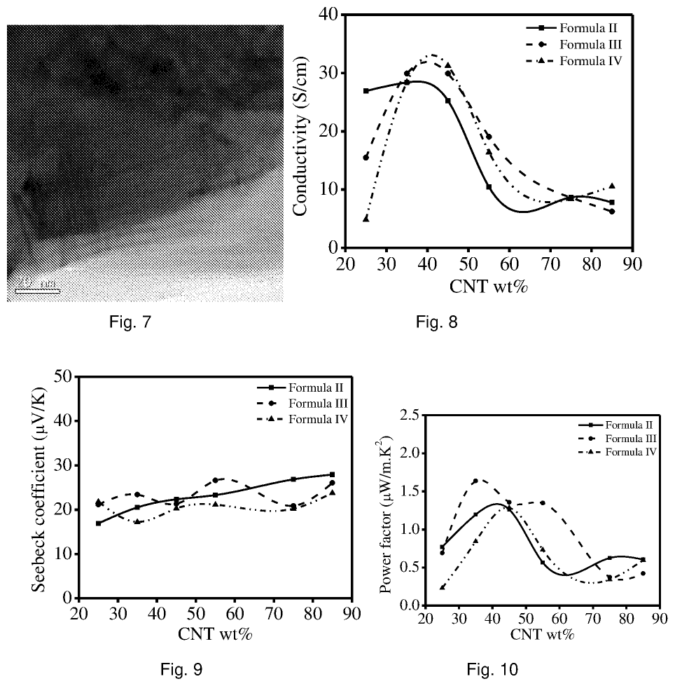

The 45 weight percent of carbon nanotube is incorporated into 55 weight percent of fused thiophene polymer matrix in the presence of 1,2-dichlorobenzene by applying ultrasonic waves. The composite is treated with ultrasonic waves of 80 kHz frequency at a low power sonication (192 W) for 1 hour at 30° C. The FIG. 6 and FIG. 7 corresponds to the microscopic image of formula IV polymer and carbon nanotube thermoelectric composite material.

### Example 4

### Preparation of Polymer Composite Using Polymer of Formula II and MWCNT

The 25 weight percent of carbon nanotube is incorporated into 75 weight percent of fused thiophene polymer matrix in the presence of 1,2-dichlorobenzene by applying ultrasonic waves. The composite is treated with ultrasonic waves of 80 kHz frequency at a low power sonication (192 W) for 1 hour at 30° C.

### Example 5

### Preparation of Polymer Composite Using Polymer of Formula III and MWCNT

The 25 weight percent of carbon nanotube is incorporated into 75 weight percent of fused thiophene polymer matrix in the presence of 1,2-dichlorobenzene by applying ultrasonic waves. The composite is treated with ultrasonic waves of 80 kHz frequency at a low power sonication (192 W) for 1 hour at 30° C.

### Example 6

### Preparation of Polymer Composite Using Polymer of Formula IV and MWCNT

The 25 weight percent of carbon nanotube is incorporated into 75 weight percent of fused thiophene polymer matrix in the presence of 1,2-dichlorobenzene by applying ultrasonic waves. The composite is treated with ultrasonic waves of 80 kHz frequency at a low power sonication (192 W) for 1 hour at 30° C.

### Example 7

### Preparation of Polymer Composite Using Polymer of Formula II and MWCNT

The 85 weight percent of carbon nanotube is incorporated into 15 weight percent of fused thiophene polymer matrix in the presence of 1,2-dichlorobenzene by applying ultrasonic waves. The composite is treated with ultrasonic waves of 80 kHz frequency at a low power sonication (192 W) for 1 hour at 30° C.

### Example 8

### Preparation of Polymer Composite Using Polymer of Formula III and MWCNT

The 85 weight percent of carbon nanotube is incorporated into 15 weight percent of fused thiophene polymer matrix in the presence of 1,2-dichlorobenzene by applying ultrasonic waves. The composite is treated with ultrasonic waves of 80 kHz frequency at a low power sonication (192 W) for 1 hour at 30° C.

### Example 9

### Preparation of Polymer Composite Using Polymer of Formula IV and MWCNT

The 85 weight percent of carbon nanotube is incorporated into 15 weight percent of fused thiophene polymer matrix in the presence of 1,2-dichlorobenzene by applying ultrasonic waves. The composite is treated with ultrasonic waves of 80 kHz frequency at a low power sonication (192 W) for 1 hour at 30° C.

### Example 10

Preparation of Thermoelectric Conversion Layer Using Polymer of Formula II and MWCNT without Doping

The thermoelectric composite material of the present invention is converted into a thermoelectric conversion layer. The thermoelectric conversion layer is formed by drop casting 20 μL of thermoelectric composite material on a glass substrate (dimension 12 mm×4 mm) and dried at 120° C. for 1 hour. The thickness of the thermoelectric conversion layer is 15 μm. The FIG. 8 to FIG. 10 show the thermoelectric properties of thermoelectric conversion layer made up of formula II polymer and carbon nanotube without doping.

### Example 11

Preparation of Thermoelectric Conversion Layer Using Polymer of Formula III and MWCNT without Doping

The thermoelectric composite material of the present invention is converted into a thermoelectric conversion layer. The thermoelectric conversion layer is formed by drop casting 20 μL of thermoelectric composite material on a glass substrate (dimension 12 mm×4 mm) and dried at 120° C. for 1 hour. The thickness of the thermoelectric conversion layer is 15 μm. The FIG. 8 to FIG. 10 show the thermoelectric properties of thermoelectric conversion layer made up of formula III polymer and carbon nanotube without doping.

### Example 12

Preparation of Thermoelectric Conversion Layer Using Polymer of Formula IV and MWCNT without Doping

The thermoelectric composite material of the present invention is converted into a thermoelectric conversion layer. The thermoelectric conversion layer is formed by drop casting 20 μL of thermoelectric composite material on a glass substrate (dimension 12 mm×4 mm) and dried at 120° C. for 1 hour. The thickness of the thermoelectric conversion layer is 15 μm. The FIG. 8 to FIG. 10 show the thermoelectric properties of thermoelectric conversion layer made up of formula IV polymer and carbon nanotube without doping.

### Example 13

Preparation of Thermoelectric Conversion Layer Using Polymer of Formula II and MWCNT with Doping

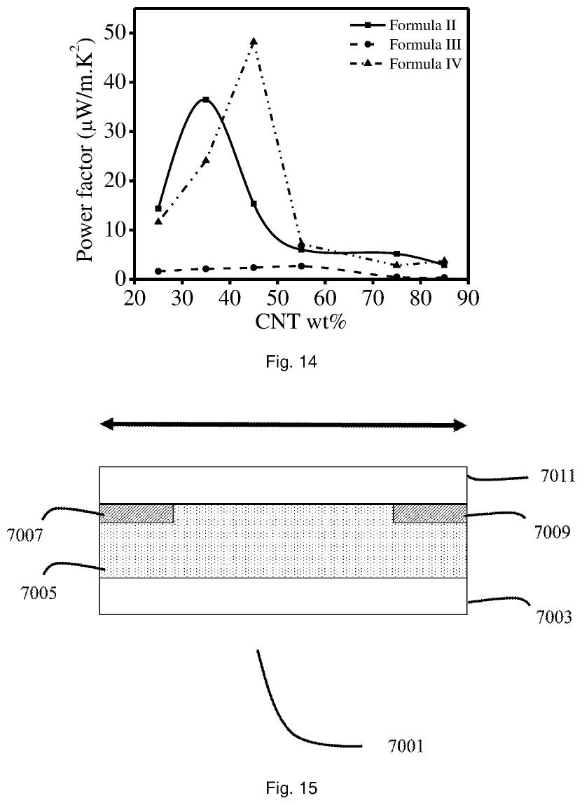

The thermoelectric composite material in the present invention contains oxidizing agent as a dopant. The thermoelectric composite material is converted to a thermoelectric conversion layer by drop casting 20 μL of thermoelectric composite material on a glass substrate (dimension 12 mm×4 mm) and dried at 120° C. for 1 hour. The thermoelectric conversion layer is soaked in 0.05 molar ferric chloride in nitromethane solution for 30 minutes at 30° C. and then dried at 100° C. for 15 minutes. The FIG. 12 to FIG. 14 show the thermoelectric properties of thermoelectric conversion layer made up of formula II polymer and carbon nanotube with doping.

### Example 14

Preparation of Thermoelectric Conversion Layer Using Polymer of Formula III and MWCNT with Doping

The thermoelectric composite material in the present invention contains oxidizing agent as a dopant. The thermoelectric composite material is converted to a thermoelectric conversion layer by drop casting 20 μL of thermoelectric composite material on a glass substrate (dimension 12 mm×4 mm) and dried at 120° C. for 1 hour. The thermoelectric conversion layer is soaked in 0.05 molar ferric chloride in nitromethane solution for 30 minutes at 30° C. and then dried at 100° C. for 15 minutes. The FIG. 12 to FIG. 14 show the thermoelectric properties of thermoelectric conversion layer made up of formula III polymer and carbon nanotube with doping.

### Example 15

Preparation of Thermoelectric Conversion Layer Using Polymer of Formula IV and MWCNT with Doping

The thermoelectric composite material in the present invention contains oxidizing agent as a dopant. The thermoelectric composite material is converted to a thermoelectric conversion layer by drop casting 20 μL of thermoelectric composite material on a glass substrate (dimension 12 mm×4 mm) and dried at 120° C. for 1 hour. The thermoelectric conversion layer is soaked in 0.05 molar ferric chloride in nitromethane solution for 30 minutes at 30° C. and then dried at 100° C. for 15 minutes. The FIG. 12 to FIG. 14 show the thermoelectric properties of thermoelectric conversion layer made up of formula IV polymer and carbon nanotube with doping.

### Example 16

### Testing the Effect of Doping Concentration on Thermoelectric Conversion Layer Using Polymer of Formula IV and MWCNT

The 45 weight percent of carbon nanotube is incorporated into 55 weight percent of fused thiophene polymer matrix in the presence of 1,2-dichlorobenzene by applying ultrasonic waves. The composite is treated with ultrasonic waves of 80 kHz frequency at a low power sonication (192 W) for 1 hour at 30° C. The thermoelectric composite material is converted to a thermoelectric conversion layer by drop casting 20 μL of thermoelectric composite material on a glass substrate (dimension 12 mm×4 mm) and dried at 120° C. for 1 hour. The thermoelectric conversion layer is soaked in different molar concentration of ferric chloride in nitromethane for 30 minutes at 30° C. and then dried at 100° C. for 15 minutes. The table 1 shows the thermoelectric properties of thermoelectric conversion layer for different concentration of dopant.

TABLE 1

| | | Dopant | | | |
|---|---|---|---|---|---|
| Formula IV | Carbon | concentra- | Thermoelectric properties | | |
| polymer | nanotube | tion | σ | α | PF = α²σ |
| (wt %) | (wt %) | (M) | (S/cm) | (μV/K) | (μW/m · K²) |
| 55 | 45 | 0 | 31.2 | 20.2 | 1.27 |
| 55 | 45 | 0.005 | 37.9 | 36.7 | 5.10 |
| 55 | 45 | 0.01 | 43.8 | 56.6 | 14.03 |
| 55 | 45 | 0.03 | 63.5 | 52.4 | 17.43 |
| 55 | 45 | 0.05 | 208.9 | 48.0 | 48.13 |
| 55 | 45 | 0.17 | 59.1 | 42.5 | 10.67 |
| 55 | 45 | 0.3 | 53.2 | 35.1 | 6.55 |

Data is obtained with a temperature difference of 10 K between the hot and cold ends.

### Example 17

### Preparation of Thermoelectric Conversion Device

In the present invention, the thermoelectric conversion device consist of a glass substrate (dimension 25 mm×25 mm). The thermoelectric conversion leg is arranged on the glass substrate in a specified area (25 mm×4 mm) by drop casting 20 μL of thermoelectric composite material of the present invention and dried at 120° C. for one hour. The pair of silver electrode is deposited by sputtering at 50 W RF power for 15 minutes on both ends of the thermoelectric conversion leg. In the thermoelectric conversion element of the present invention, the thickness of the thermoelectric conversion leg is 15 μm.

Referring to FIG. 15, a thermoelectric device (7001) comprises, the first element which is a substrate preferably glass (7003), a thermoelectric conversion leg (7005) of thermoelectric composite material of the present invention arranged on first element (7003), and a pair of electrodes including first electrode (7007) and second electrode (7009) preferably silver electrodes arranged thereon. A second element which is a substrate preferably PET (7011) is arranged top of this to protect the thermoelectric conversion legs from surrounding.

The thermoelectric conversion device of the present invention may have one, two or multiple thermoelectric conversion legs. In the thermoelectric conversion device of the present invention, the number of thermoelectric conversion leg is preferably 1 to 10, and is increased indeterminately based on applications.

In the thermoelectric conversion device, the thermoelectric composite material of the present invention is preferably arranged on the substrate in the film form, and this substrate is preferably functioned as the above-described first element (7003). More specifically, it is preferably that the thermoelectric composite material of the present invention is arranged on a substrate surface and above-mentioned electrode materials are arranged thereon. The electrode materials in the thermoelectric conversion device of the present invention may deposit by blade coating, spray coating, extrusion die coating, roll coating, bar coating, screen printing, curtain coating, stencil printing, dip coating, painting, vapour deposition techniques or the like.

The thermoelectric conversion leg thus formed has a substrate on one surface. It is preferable that the other surface of the leg is also covered with a substrate, the second element (7011), for the protection of the film, using adhesive tapes.

### Example 18

### Testing of Thermoelectric Conversion Device in the Power Generation Mode

The thermoelectric conversion device is used suitably as a power generation device. A temperature difference applied between the two ends of the thermoelectric conversion leg (7005) is at least 50° C. and the electrical potential is tapped across two electrodes (7007, 7009). The temperature on one end is maintained in a range from 80° C. via the resistive heater. The temperature on other end is maintained in a range from 30° C. via the Peltier cooler. The temperature difference (ΔT) is measured using two thermocouples attached to the first and second electrodes (7007, 7009). A nanovoltmeter is used to measure the voltage difference (ΔV) with connection leads. The temperature and voltage differences are measured simultaneously.

The normalized thermoelectric conversion device performance of an embodiment is shown in table 3. Table 4 shows the normalized thermoelectric conversion device performance of an embodiment, in which the thermoelectric composite material is with or without doping.

TABLE 3

| Formula IV | Carbon | | | Power |
|---|---|---|---|---|
| polymer | nanotube | Current | Voltage | output |
| (wt %) | (wt %) | (μA) | (mV) | (nW) |
| 75 | 25 | 0.89 | 1.18 | 1.06 |
| 65 | 35 | 2.05 | 1.04 | 2.13 |
| 55 | 45 | 3.45 | 1.26 | 4.34 |
| 45 | 55 | 2.69 | 1.44 | 3.87 |
| 35 | 65 | 1.93 | 1.63 | 3.17 |
| 15 | 85 | 1.50 | 1.71 | 2.57 |

Data is obtained with a temperature difference of 50 K between the hot and cold ends.

TABLE 4

| Formula IV | Carbon | Dopant | | | Power |
|---|---|---|---|---|---|
| polymer | nanotube | concentration | Current | Voltage | output |
| (wt %) | (wt %) | (M) | (μA) | (mV) | (nW) |
| 55 | 45 | 0 | 3.45 | 1.26 | 4.34 |
| 55 | 45 | 0.05 | 8.08 | 1.55 | 12.60 |

Data is obtained with a temperature difference of 50 K between the hot and cold ends.

### ADVANTAGES OF THE INVENTION

Polymer nanocomposite based thermoelectric materials are a new class of functional materials that are low-cost, light-weight and bendable/flexible compared to the conventional materials. For these reason these have immense potential for commercial usage. The present invention describes the preparation of highly efficient and stable thermoelectric layer using a novel composite based on some fused thiophene polymers and carbon nanotubes. The composites are stable up to ˜350° C. and could be used for on-the-spot sustainable power generation from thermal sources like hot water released by process plants, automotive exhausts, and even human/mammal body heat.

1. A thermoelectric composite material comprising
i. 15 to 75 weight percent a semiconducting polymer of formula I;
ii. 25 to 85 weight percent a carbon nanotube structure, 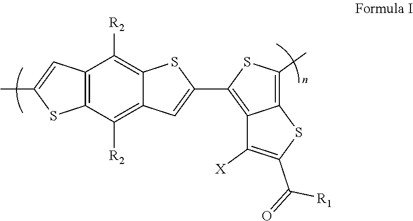
wherein
R₁=—C₇H₁₅;
R₂ is identical and selected from 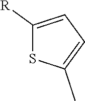
or —OR
R=—C₈H₁₇;
X=H or F when R₂ is 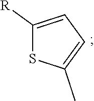
X=H when R₂ is —OR.

2. The thermoelectric composite material as claimed in claim 1, wherein thermoelectric composite material comprising, 15 to 75 weight percent a semiconducting polymer of formula I, 25 to 85 weight percent a carbon nanotube structure optionally along with 0.005 to 0.3 molar concentration of a dopant.

3. The thermoelectric composite material as claimed in claim 1, wherein formula I is selected from the group consisting of:

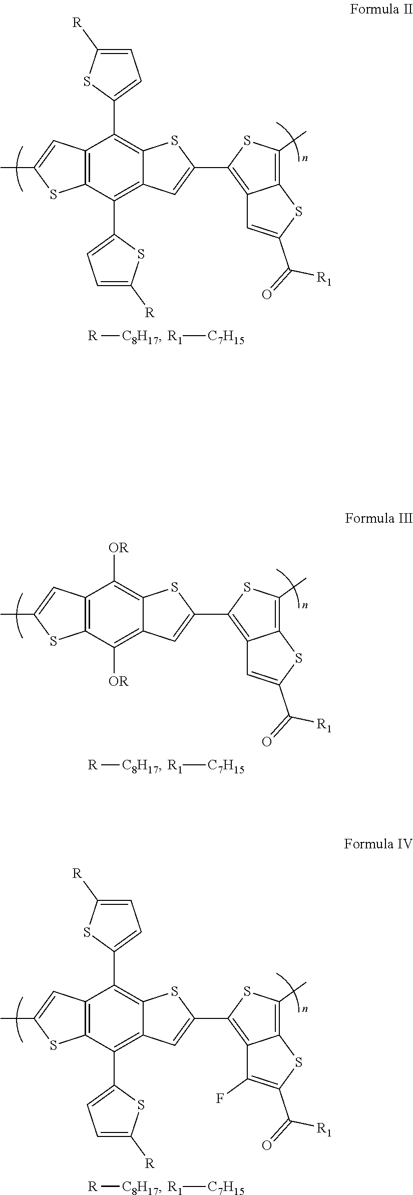

4. The thermoelectric composite material as claimed in claim 1, wherein the carbon nanotubes is selected from single-walled, double-walled, and/or multi-walled carbon nanotubes.

5. The thermoelectric composite material as claimed in claim 2, wherein the dopant used is selected from a group consisting of an onium salt compound, an oxidizing agent, an acidic compound and an electron acceptor compound.

6. The thermoelectric composite material as claimed in claim 2, wherein the dopant is a transition metal using its salt compound.

7. The thermoelectric composite material of claim 1, wherein the composite material is stable up to 350° C. and is capable of producing a potential difference in response to a temperature gradient.

8. A process for the preparation of thermoelectric composite material as claimed in claim 1 comprising the steps of:
i. incorporating 25 to 85 weight percent of carbon nanotube in 15 to 75 weight percent of fused thiophene based semiconducting polymer of formula I in the presence of a solvent followed by applying ultrasonic waves for 45 to 65 min to obtain thermoelectric composite materials.

9. A thermoelectric conversion device comprising serially connected single or multiple planar legs made of a thermoelectric composite material as claimed in claim 1, casted on a substrate or made as a free-standing leg and supported by the second substrate for insulation from the surrounding.

10. The device as claimed in claim 1, wherein conductivity of the device is in the range of 400 S/m to 2000 S/m.
